(19) United States
(12) Patent Application Publication
(10) Pub. No.: US 2026/0164797 A1
(43) Pub. Date: Jun. 11, 2026

(54) DISPLAY PANEL AND DISPLAY DEVICE

(71) Applicant: WUHAN CHINA STAR OPTOELECTRONICS SEMICONDUCTOR DISPLAY TECHNOLOGY CO., LTD., Wuhan, Hubei (CN)

(72) Inventors: Feixiang SUN, Wuhan, Hubei (CN); Yi LIU, Wuhan, Hubei (CN)

(73) Assignee: WUHAN CHINA STAR OPTOELECTRONICS SEMICONDUCTOR DISPLAY TECHNOLOGY CO., LTD., Wuhan, Hubei (CN)

(21) Appl. No.: 18/705,660

(22) PCT Filed: Apr. 2, 2024
(86) PCT No.: PCT/CN2024/085504

§ 371 Date: Apr. 29, 2024

(30) Foreign Application Priority Data
Mar. 27, 2024 (CN) 202410365823.8

(51) Int. Cl. H10D 86/40; G09G 3/32; H10H 29/49

(52) U.S. Cl. CPC H10D 86/441; G09G 3/32; H10D 86/481; G09G 2300/0408; G09G 2300/0426; G09G 2300/043; G09G 2310/0267; G09G 2310/06; H10H 29/49

(57) ABSTRACT

A display panel and a display device are provided, improving the stability of output signals from a gate driving circuit by connecting a first capacitor and a second capacitor to a second power line which is also connected to a second output transistor. This configuration increases the overall capacitance on the second power line, reduces the voltage drop across the second power line, and mitigates the issue of fluctuations in the high-level output of conventional GOA circuits affecting the stability of the output signals.

### TECHNICAL FIELD

The present application relates to a field of display technology, and in particular, to a display panel and a display device.

### DESCRIPTION OF RELATED ART

As the display requirements for display panels continuously increase, Gate driver On Array (GOA, with gate drivers directly integrated on a thin-film transistor array substrate) circuits are also gradually being improved and perfected. The output signals of the gate driving circuit directly affect the display effect, and therefore, optimizing the stability of the output signals is extremely important. However, existing GOA circuits can experience significant disturbances when outputting signals into the plane, causing fluctuations in the output high level, which affects the stability of the output signals.

### SUMMARY OF INVENTION

The present application provides a display panel and a display device to alleviate the technical issue where the high-level output of existing GOA circuits can experience certain fluctuations, affecting the stability of the output signals.

In order to solve the above problems, the technical solutions provided by this application are as follows:
In one aspect, the present application provides a display panel, including a first power line and a second power line arranged along a first direction and spaced apart along a second direction, wherein the first direction and the second direction are different; and multiple stages of gate driving circuits in a cascaded arrangement, wherein the gate driving circuits are configured to generate multiple gate control signals for output to a plurality of sub-pixels of the display panel, and each of the gate driving circuits includes:
a start transistor, wherein a gate of the start transistor is configured to receive a corresponding clock signal, and a source of the start transistor is configured to receive a start signal;
a first output transistor, wherein a gate of the first output transistor is electrically connected to a drain of the start transistor, a source of the first output transistor is connected to the first power line, and a drain of the first output transistor is connected to a first output line of the gate driving circuit of the current stage;
a first capacitor, wherein a first plate of the first capacitor is connected to the gate of the first output transistor;
a second output transistor, wherein a gate of the second output transistor is electrically connected to the gate of the first output transistor, a source of the second output transistor is connected to the second power line, and a drain of the second output transistor is connected to a second output line of the gate driving circuit of the current stage; and
a second capacitor, wherein a first plate of the second capacitor is connected to the gate of the second output transistor and electrically connected to the first plate of the first capacitor, wherein a second plate of the second capacitor is connected to a second plate of the first capacitor, also connected to the source of the second output transistor, and is connected through the source of the second output transistor to the second power line.

In a second aspect, the present application provides a display device, including a display panel. The display panel includes a first power line and a second power line arranged along a first direction and spaced apart along a second direction, wherein the first direction and the second direction are different; and multiple stages of gate driving circuits in a cascaded arrangement, wherein the gate driving circuits are configured to generate multiple gate control signals for output to a plurality of sub-pixels of the display panel, and each of the gate driving circuits includes:
a start transistor, wherein a gate of the start transistor is configured to receive a corresponding clock signal, and a source of the start transistor is configured to receive a start signal;
a first output transistor, wherein a gate of the first output transistor is electrically connected to a drain of the start transistor, a source of the first output transistor is connected to the first power line, and a drain of the first output transistor is connected to a first output line of the gate driving circuit of the current stage;
a first capacitor, wherein a first plate of the first capacitor is connected to the gate of the first output transistor;
a second output transistor, wherein a gate of the second output transistor is electrically connected to the gate of the first output transistor, a source of the second output transistor is connected to the second power line, and a drain of the second output transistor is connected to a second output line of the gate driving circuit of the current stage; and
a second capacitor, wherein a first plate of the second capacitor is connected to the gate of the second output transistor and electrically connected to the first plate of the first capacitor, wherein a second plate of the second capacitor is connected to a second plate of the first capacitor, also connected to the source of the second output transistor, and is connected through the source of the second output transistor to the second power line.

### BRIEF DESCRIPTION OF DRAWINGS

To more clearly illustrate the technical solutions in the embodiments or conventional technology, the drawings needed to be used in the description of the embodiments or the conventional technology are briefly introduced below. It is evident that the drawings described below are only some embodiments of the present application. For those skilled in the art, other drawings can also be obtained from these drawings without creative effort.

FIG. 1 is a schematic plan view of a display panel provided in one embodiment of the present application.

FIG. 2 is a schematic circuit diagram of a gate driving circuit provided in one embodiment of the present application.

FIG. 3 is a schematic plan view of the gate driving according to one embodiment of the present application.

FIG. 4a is a schematic plan view of an active layer of each transistor in FIG. 3.

FIG. 4b is a schematic plan view of a first metal layer in FIG. 3.

FIG. 4c is a schematic view of a stack-up of the active layer from FIG. 4a with the first metal layer from FIG. 4b.

FIG. 5a is a schematic plan view of a light-shielding layer in FIG. 3.

FIG. 5b is a schematic view of a stack-up of the light-shielding layer from FIG. 3 with FIG. 4c.

FIG. 6a is a schematic plan view of a second metal layer in FIG. 3.

FIG. 6b is a schematic view of a stack-up of the second metal layer from FIG. 6a with the first metal layer from FIG. 4b.

FIG. 7a is a schematic plan view of vias in an interlayer dielectric layer in FIG. 3.

FIG. 7b is a schematic view of a stack-up of FIG. 7a with FIG. 6b.

FIG. 8a is a schematic plan view of a third metal layer in FIG. 3.

FIG. 8b is a schematic view of a stack-up of FIG. 8a with FIG. 6b.

FIG. 9a is a schematic plan view of vias in the planarization layer in FIG. 3.

FIG. 9b is a schematic view of a stack-up of FIG. 9a with FIG. 8b.

FIG. 10a is a schematic plan view of a fourth metal layer in FIG. 3.

FIG. 10b is a schematic view of a stack-up of FIG. 10a with FIG. 9b.

FIG. 11a is a schematic diagram of a waveform of output signals at various stages of gate driving circuits in conventional technology.

FIG. 11b is a schematic diagram of a waveform of output signals at various stages of the gate driving circuits provided in one embodiment of the present application.

### DETAILED DESCRIPTION OF EMBODIMENTS OF THE INVENTION

The descriptions of the following embodiments are with reference to the accompanying drawings, used to exemplify specific embodiments that can be implemented according to the present application. The directional terms mentioned in this application, such as “up”, “down”, “front”, “back”, “left”, “right”, “inner”, “outer”, “side”, etc., are only in reference to the directions in the accompanying drawings. Therefore, the use of directional terms is for explaining and understanding this application and is not intended to limit the application. In the drawings, structurally similar units are denoted with the same reference numerals. In the drawings, for clear understanding and ease of description, the thickness of some layers and areas has been exaggerated. That is, the dimensions and thickness of each component shown in the drawings are not to scale, and this application is not limited in this regard.

Addressing the issue where the high-level output of existing GOA circuits can experience certain fluctuations affecting the stability of output signals, the inventor of this application discovered through research that this is primarily due to the fact that when the GOA circuit outputs high levels, the output transistors are turned on. At this time, a momentary large current passes through the output transistors when the high-level power line outputs, causing a certain voltage drop in the high-level power line. This leads to fluctuations in the output high levels, thereby affecting the stability of the output signals.

To this end, this application provides a display panel and a display device to improve the aforementioned problem.

In one embodiment, the present application provides a display panel that includes a first power line and a second power line arranged along a first direction and spaced apart along a second direction, where the first direction and the second direction are different. The display panel also includes multiple stages of gate driving circuits in a cascaded arrangement. The gate driving circuits are configured to generate multiple gate control signals for output to a plurality of sub-pixels of the display panel. Each gate driving circuit includes:
a start transistor, whose gate is configured to receive a corresponding clock signal, whose source is configured to receive a start signal;
a first output transistor, whose gate is electrically connected to a drain of the start transistor, whose source is connected to the first power line, and whose drain is connected to a first output line of the current stage gate driving circuit;
a first capacitor, whose first plate is connected to the gate of the first output transistor;
a second output transistor, whose gate is electrically connected to the gate of the first output transistor, whose source is connected to the second power line, and whose drain is connected to a second output line of the current stage gate driving circuit; and
a second capacitor, whose first plate is connected to the gate of the second output transistor and electrically connected to the first plate of the first capacitor, whose second plate is connected to a second plate of the first capacitor, and also connected to the source of the second output transistor, and is connected through the source of the second output transistor to the second power line.

In one embodiment, each gate driving circuit further includes a third capacitor. A second plate of the third capacitor is connected to the second plate of the second capacitor.

In one embodiment, each gate driving circuit further includes a first frequency dividing transistor. A gate of the first frequency dividing transistor is connected to a first plate of the third capacitor. A source of the first frequency dividing transistor is connected to the first plate of the first capacitor. A drain of the first frequency dividing transistor is connected to the first plate of the second capacitor.

In one embodiment, the first plates of the first, second, and third capacitors are integrally formed and located between the first power line and the second power line.

In one embodiment, the gate of the second output transistor includes a plurality of first sub-traces extending along the second direction, a first gap is established between each adjacent pair of the first sub-traces, each of the first sub-traces is connected to the first plate of the second capacitor, and the first plate of the second capacitor is located on a same side of the first sub-traces and extends along the first direction;
the source of the second output transistor includes a plurality of second sub-traces extending along the second direction and a third sub-trace that connects the second sub-traces, the third sub-trace extends along the first direction, the third sub-trace is disposed corresponding to the second plate of the second capacitor and is connected to the second plate of the second capacitor, and the second sub-traces are connected to the second power line;
the drain of the second output transistor includes a plurality of fourth sub-traces extending along the second direction and a fifth sub-trace that connects the fourth sub-traces, the fifth sub-trace extends along the first direction and is disposed on one side of the fourth sub-traces away from the third sub-trace, and the fifth sub-trace is connected to the second output line;
wherein both the second sub-traces and the fourth sub-traces are arranged corresponding to the first gaps and are located on two opposite sides of the first sub-traces.

In one embodiment, the second power line includes a first sub-power line and a second sub-power line, the second output transistors within some of the gate driving circuits are connected to the first sub-power line, while the second output transistors within the remaining gate driving circuits are connected to the second sub-power line.

In one embodiment, among any two adjacent stages of the gate driving circuits, the second output transistor within one stage of the gate driving circuits is connected to the first sub-power line, while the second output transistor within the other stage of the gate driving circuits is connected to the second sub-power line.

In one embodiment, the display panel further includes:
a substrate;
a first metal layer disposed on the substrate, wherein the first metal layer includes the gate of the first output transistor, the gate of the second output transistor, the first plate of the first capacitor, the first plate of the second capacitor, a first plate of the third capacitor, and the second output line;
a second metal layer disposed on one side of the first metal layer away from the substrate, wherein the second metal layer comprises the second plate of the first capacitor, the second plate of the second capacitor, and the second plate of the third capacitor;
a third metal layer disposed on one side of the second metal layer away from the first metal layer, wherein the third metal layer includes the source of the first output transistor, the drain of the first output transistor, the source of the second output transistor, the drain of the second output transistor, and the first output line; and
a fourth metal layer disposed on one side of the third metal layer away from the second metal layer, wherein the fourth metal layer includes the first power line and the second power line.

In one embodiment, the display panel further includes a third power line extending along the first direction, with the third power line located on one side of the second power line away from the first power line,
wherein each of the gate driving circuits further includes a third output transistor and a fourth output transistor, a gate of the third output transistor is connected to a gate of the fourth output transistor, a source of the third output transistor is connected to a source of the fourth output transistor, a drain of the third output transistor is connected to the first output line, the source of the fourth output transistor is connected to the third power line, and a drain of the fourth output transistor is connected to the second output line.

In one embodiment, along the second direction, a width of the third power line is greater than a width of both the second power line and the first power line.

In another embodiment, this application also provides a display device, which includes the display panel from one of the previously described embodiments.

In the display panel and the display device provided in this application, by connecting the first and second capacitors to the second power line which is connected to the second output transistor, the overall capacitance on the second power line is increased, reducing the voltage drop on the second power line and improving the stability of the output signals from the gate driving circuits. This addresses the issue where the high-level output of conventional GOA circuits can experience certain fluctuations, affecting the stability of the output signals.

In conjunction with the accompanying drawings and through specific embodiments, the following further explains the display panel and the display device described in this application.

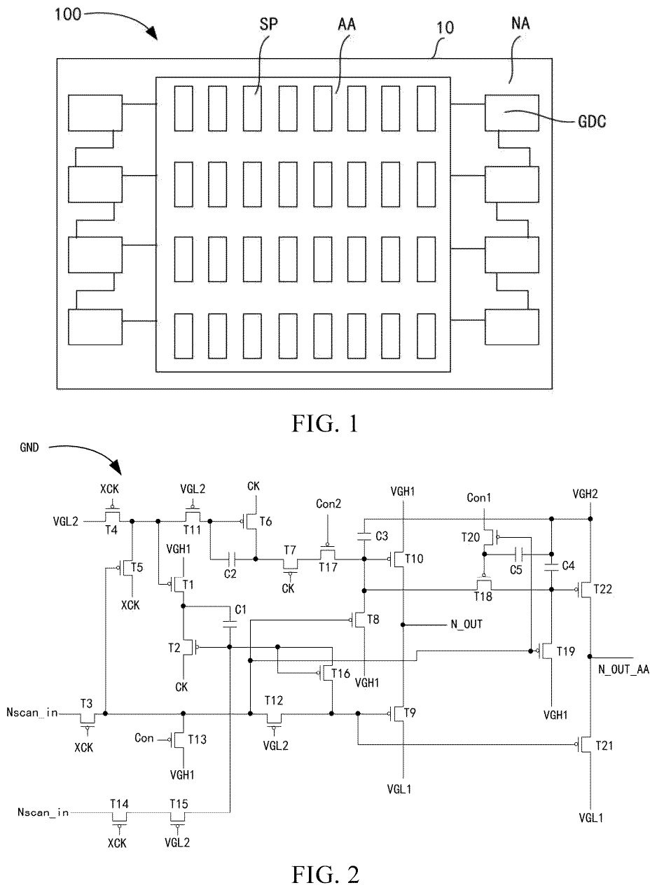

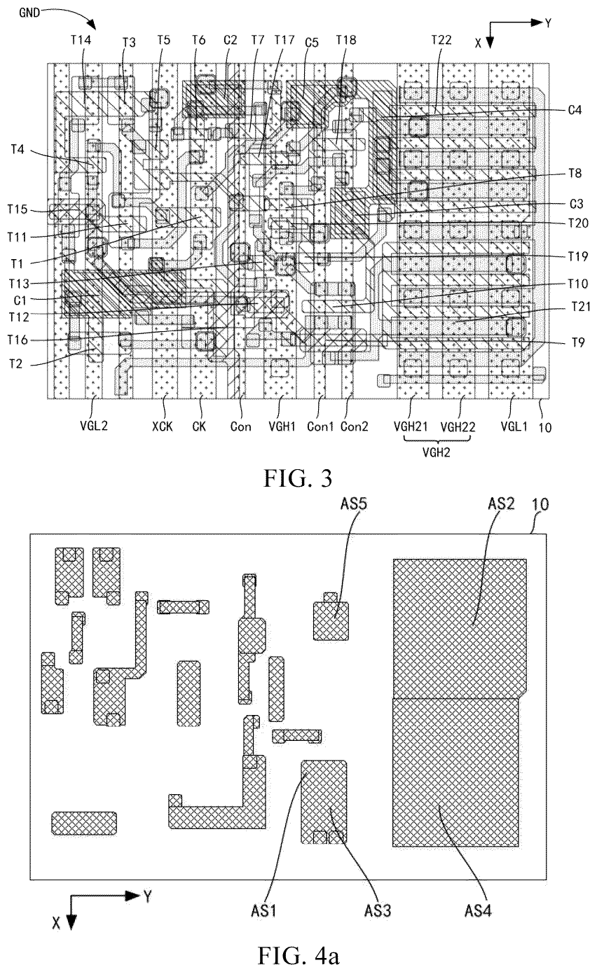

Please refer to FIGS. 1 to 3. FIG. 1 is a schematic plan view of the display panel according to one embodiment of the present application, FIG. 2 is a schematic circuit diagram of a gate driving circuit provided in one embodiment of this application, and FIG. 3 is a schematic plan view of the gate driving provided in one embodiment of this application. Referring to FIG. 1, the display panel 100 includes a substrate 10 and an array of multiple sub-pixels SP arranged on the substrate 10. Optionally, the sub-pixels SP include red, green, and blue sub-pixels; the red sub-pixels emit red light, the green sub-pixels emit green light, and the blue sub-pixels emit blue light, to achieve color display on the display panel 100.

The display panel 100 further includes multiple stages of cascaded gate driving circuits (GDC). The gate driving circuits GDC are configured to generate multiple gate control signals for output to the sub-pixels SP of the display panel 100, such as each gate driving circuit GDC controlling a row or two rows of sub-pixels SP. Optionally, the display panel 100 further includes a display area (AA) and a non-display area (NA) located on one side of the display area AA. The sub-pixels SP are located within the display area AA, and the gate driving circuits GDC are located in the non-display area NA.

Referring to FIGS. 1 and 2, each gate driving circuit GDC includes at least a start transistor T3 and a first output transistor T10. A gate of the start transistor T3 is configured to receive a corresponding clock signal (such as the first clock signal line XCK), a source of the start transistor T3 is configured to receive a start signal (such as the start signal Nscan_in), and a drain of the start transistor T3 is electrically connected to a gate of the first output transistor T10.

Wherein, the multiple stages of gate driving circuits GDC cascaded after the first stage gate driving circuit GDC can receive a first control signal (such as a first control signal N_OUT) output from the first output transistor T10 of the previous stage gate driving circuit GDC as the start signal, and the first stage gate driving circuit GDC, among the multiple stages, can receive a control signal generated by a timing controller or similar device as the start signal.

Optionally, the n-th stage gate driving circuit GDC(n) receives the first control signal output from the first output transistor T10 of the (n-A)th stage gate driving circuit GDC(n-A) as the start signal; where A ≥1. If the multiple stages of gate driving circuits GDC are designed with a cascading row-by-row approach, then the n-th stage gate driving circuit GDC(n) receives the control signal output from the first output transistor T10 of the (n-1)th stage gate driving circuit GDC(n-1) as the start signal.

Referring to FIGS. 2 and 3, the display panel 100 also includes a first power line VGH1 and a second power line VGH2, which extend along a first direction X and are spaced apart along a second direction Y. The first direction X and the second direction Y are different, for example, the first direction X is a column direction and the second direction Y is a row direction, with the first direction X perpendicular to the second direction Y. A source of the first output transistor T10 is connected to the first power line VGH1, and a drain of the first output transistor T10 is connected to a first output line of the respective stage of the gate driving circuit GDC. The first output line is used to output the first control signal N_OUT output from the first output transistor T10.

Each gate driving circuit GDC further includes a first capacitor C3, a second output transistor T22, and a second capacitor C4. A first plate of the first capacitor C3 is connected to a gate of the first output transistor T10, a gate of the second output transistor T22 is electrically connected to the gate of the first output transistor T10, a source of the second output transistor T22 is connected to the second power line VGH2, and a drain of the second output transistor T22 is connected to a second output line of the respective stage of the gate driving circuit GDC. The second output line is used to output a gate control signal N_out_AA output by the second output transistor T22 to the sub-pixels SP within the display area AA of the display panel 100, to control the opening and closing of the sub-pixels SP. A first plate of the second capacitor C4 is connected to the gate of the second output transistor T22 and electrically connected to the first plate of the first capacitor C3. A second plate of the second capacitor C4 is connected to a second plate of the first capacitor C3, and also connected to the source of the second output transistor T22, and through the source of the second output transistor T22 connected to the second power line VGH2. It should be noted that in this application, “connected” refers to two structures being in direct contact or directly connected through wires, etc., while “electrically connected” refers to an electrical connection between two structures facilitated by switching devices, etc.

In this embodiment, by connecting the first capacitor C3 and the second capacitor C4 to the second power line VGH2 which is connected to the second output transistor T22, the overall capacitance on the second power line VGH2 is increased. This reduces the voltage drop on the second power line VGH2 and enhances the stability of the output signals from the gate driving circuit GDC. Thus, it addresses the technical issue where the high-level output of conventional GOA circuits can experience certain fluctuations, affecting the stability of the output signals.

In one embodiment, each gate driving circuit GDC also includes a third capacitor C5, where a second plate of the third capacitor C5 is connected to the second plate of the second capacitor C4. Each gate driving circuit GDC also includes a first frequency dividing transistor T18, with a gate of the first frequency dividing transistor T18 connected to a first plate of the third capacitor C5, a source of the first frequency dividing transistor T18 connected to the first plate of the first capacitor C3, and a drain of the first frequency dividing transistor T18 connected to the first plate of the second capacitor C4. Optionally, the first plate of the first capacitor C3, the first plate of the second capacitor C4, and the first plate of the third capacitor C5 are integrally formed and located between the first power line VGH1 and the second power line VGH2.

The display panel 100 also includes a third power line VGL1 and a fourth power line VGL2 extending along the first direction X. The third power line VGL1 is located on one side of the second power line VGH2, away from the first power line VGH1, and the fourth power line VGL2 is located on one side of the first power line VGH1, away from the second power line VGH2. Along the second direction Y, a width of the third power line VGL1 is greater than widths of both the second power line VGH2 and the first power line VGH1. The third power line VGL1 and the fourth power line VGL2 are low-level power lines, while the first power line VGH1 and the second power line VGH2 are high-level signal lines, with the voltages on the first power line VGH1 and the second power line VGH2 being higher than the voltages on the third power line VGL1 and the fourth power line VGL2.

Each gate driving circuit GDC also includes a third output transistor T9 and a fourth output transistor T21. A gate of the third output transistor T9 is connected to a gate of the fourth output transistor T21, a source of the third output transistor T9 is connected to a source of the fourth output transistor T21, a drain of the third output transistor T9 is connected to the first output line, the source of the fourth output transistor T21 is connected to the third power line VGL1, and a drain of the fourth output transistor T21 is connected to the second output line.

The display panel 100 further includes along the first direction X, a first clock signal line XCK, a second clock signal line CK, a power-on reset control line Con, a first frequency division control signal line Con2, and a second frequency division control signal line Con1.

The gate driving circuit GDC further includes a first transistor T4, a second transistor T5, a third transistor T6, a fourth transistor T7, a fifth transistor T8, a sixth transistor T1, a seventh transistor T2, a fourth capacitor C2, and a fifth capacitor C1.

A gate of the first transistor T4 is connected to the gate of the start transistor T3, and the gate of the start transistor T3 is connected to the first clock signal line XCK. The first clock signal line XCK is used to provide a clock signal to the start transistor T3. A source of the first transistor T4 is connected to the fourth power line VGL2.

A gate of the second transistor T5 is connected to the drain of the start transistor T3, a source of the second transistor T5 is connected to the first clock signal line XCK, and a drain of the second transistor T5 is connected to a drain of the first transistor T4.

A gate of the third transistor T6 is electrically connected to the drain of the first transistor T4, and a source of the third transistor T6 is connected to the second clock signal line CK.

A gate of the fourth transistor T7 is connected to the second clock signal line CK, and a source of the fourth transistor T7 is connected to a drain of the third transistor T6.

A gate of the fifth transistor T8 is connected to a gate of the second transistor T5. The gate of the second transistor T5 is electrically connected to the drain of the start transistor T3. A source of the fifth transistor T8 is connected to the first power line VGH1. A drain of the fifth transistor T8 is electrically connected to a drain of the fourth transistor T7, and also connected to the first plate of the first capacitor C3.

A gate of the sixth transistor T1 is electrically connected to the drain of the first transistor T4, and a source of the sixth transistor T1 is electrically connected to the first power line VGH1.

A source of the seventh transistor T2 is connected to the second clock signal line CK, and a drain of the seventh transistor T2 is connected to a drain of the sixth transistor T1.

The gate of the first output transistor T10 is electrically connected to the drain of the fourth transistor T7, the source of the first output transistor T10 is connected to the first power line VGH1, and the drain of the first output transistor T10 is electrically connected to the drain of the third output transistor T9.

A first plate of the fourth capacitor C2 is connected to the gate of the third transistor T6, and a second plate of the fourth capacitor C2 is electrically connected to the drain of the third transistor T6.

A first plate of the fifth capacitor C1 is electrically connected to a gate of the seventh transistor T2, and a second plate of the fifth capacitor C1 is connected to the drain of the seventh transistor T2.

Optionally, in one gate driving circuit GDC among two adjacent stages of gate driving circuits GDC, the gate of the start transistor T3 is configured to receive the first clock signal XCK, while the gate of the fourth transistor T7 is configured to receive the second clock signal CK. In the other gate driving circuit GDC of the two adjacent stages, the gate of the start transistor T3 is configured to receive the second clock signal CK, and the gate of the fourth transistor T7 is configured to receive the first clock signal XCK.

Optionally, the gates of the start transistors T3 in odd-numbered stages of gate driving circuits GDC are configured to receive the first clock signal XCK, and the gates of the start transistors T3 in even-numbered stages are configured to receive the second clock signal CK. The gates of the fourth transistors T7 in odd-numbered stages are configured to receive the second clock signal CK, while the gates of the fourth transistors T7 in even-numbered stages are configured to receive the first clock signal XCK.

Optionally, the gate driving circuit GDC further includes a first shielding transistor T11 and a second shielding transistor T12.

A source of the first shielding transistor T11 is connected to the drain of the first transistor T4 and the gate of the sixth transistor T1. A drain of the first shielding transistor T11 is connected to the gate of the third transistor T6, and a gate of the first shielding transistor T11 is connected to the fourth power line VGL2.

A source of the second shielding transistor T12 is connected to the gates of both the fifth transistor T8 and the second transistor T5. A drain of the second shielding transistor T12 is electrically connected to the gate of the third output transistor T9, and a gate of the second shielding transistor T12 is connected to the fourth power line VGL2.

Optionally, both the first shielding transistor T11 and the second shielding transistor T12 are P-type transistors. The gate of the first shielding transistor T11 is electrically connected to the fourth power line VGL2, and the gate of the second shielding transistor T12 is electrically connected to the fourth power line VGL2. If the first and second shielding transistors T11 and T12 are N-type transistors, then the gates of the first shielding transistor T11 and the second shielding transistor T12 are electrically connected to the first power line VGH1.

Optionally, the gate driving circuit GDC further includes an eighth transistor T16 and a ninth transistor T14.

A gate and a source of the eighth transistor T16 are connected to the gate of the seventh transistor T2. A drain of the eighth transistor T16 is connected to the gate of the third output transistor T9, and is also connected to the drain of the second shielding transistor T12.

A gate of the ninth transistor T14 is connected to the gate of the start transistor T3, a source of the ninth transistor T14 is connected to the source of the start transistor T3, and a drain of the ninth transistor T14 is electrically connected to the gate of the seventh transistor T2.

Optionally, the gate driving circuit GDC further includes a third shielding transistor T15. A source of the third shielding transistor T15 is connected to the drain of the ninth transistor T14, and a drain of the third shielding transistor T15 is connected to the first plate of the fifth capacitor C1. Optionally, if the third shielding transistor T15 is a P-type transistor, its gate is electrically connected to the fourth power line VGL2. If the third shielding transistor T15 is an N-type transistor, its gate is electrically connected to the first power line VGH1.

Optionally, the gate driving circuit GDC further includes a tenth transistor T13. A gate of the tenth transistor T13 is connected to the power-on reset control line Con, a source of the tenth transistor T13 is connected to the first power line VGH1, and a drain of the tenth transistor T13 is connected to the source of the second shielding transistor T12.

Optionally, the gate driving circuit GDC also includes a second frequency dividing transistor T17. A gate of the second frequency dividing transistor T17 is connected to the first frequency division control signal line Con2, a source of the second frequency dividing transistor T17 is connected to the drain of the fourth transistor T7, and a drain of the second frequency dividing transistor T17 is connected to the drain of the fifth transistor T8.

Optionally, the gate driving circuit GDC further includes a third frequency dividing transistor T20 and a fourth frequency dividing transistor T19.

A gate of the third frequency dividing transistor T20 is connected to a gate of the fourth frequency dividing transistor T19 and also to the gate of the fifth transistor T8. A source of the third frequency dividing transistor T20 is connected to the second frequency division control signal line Con1. The gate of the first frequency dividing transistor T18 is connected to a drain of the third frequency dividing transistor T20.

A source of the fourth frequency dividing transistor T19 is connected to the first power line VGH1, and a drain of the fourth frequency dividing transistor T19 is connected to the gate of the second output transistor T22.

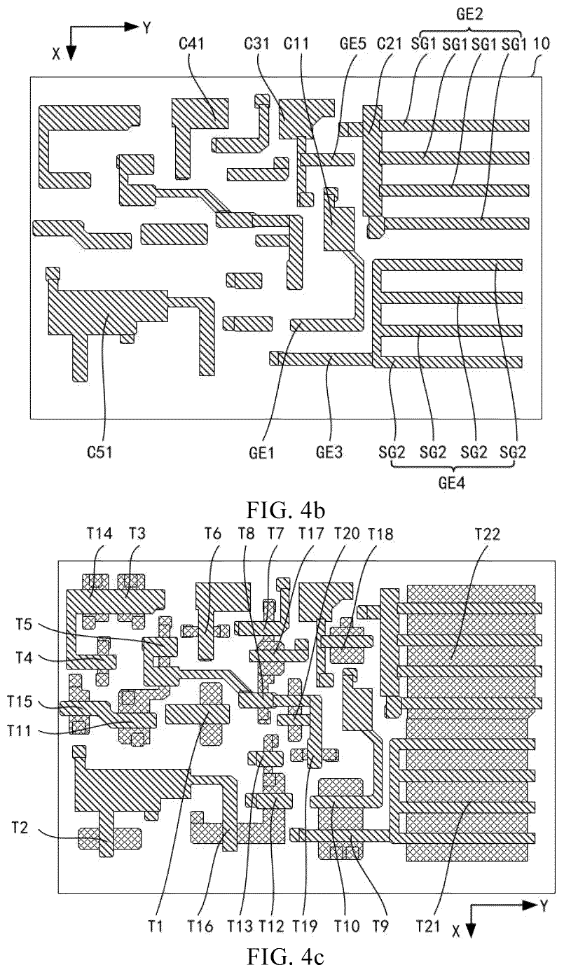

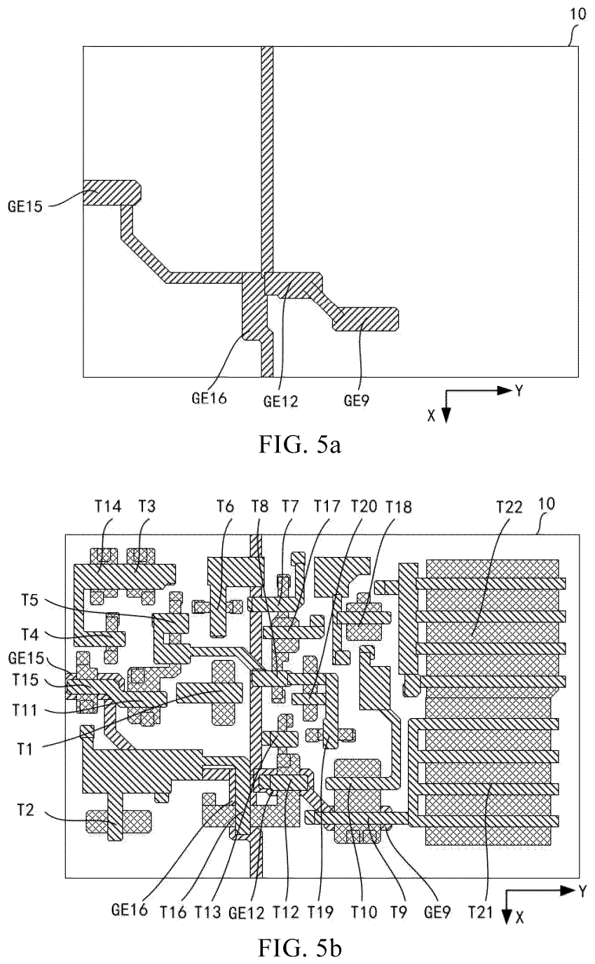

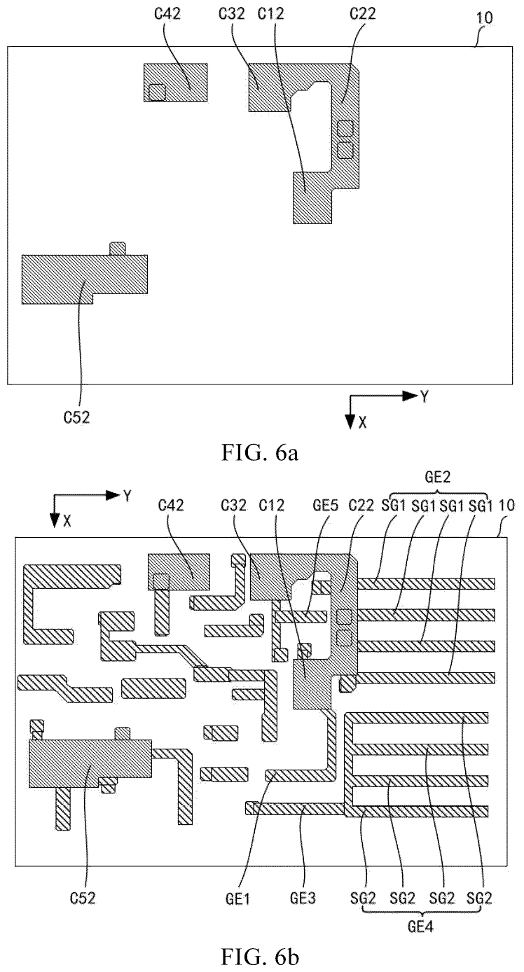

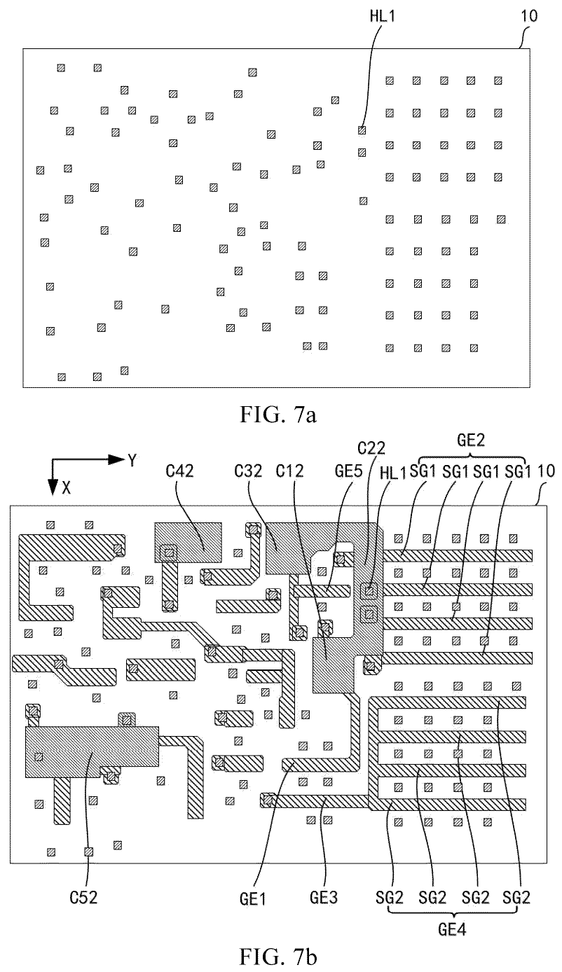

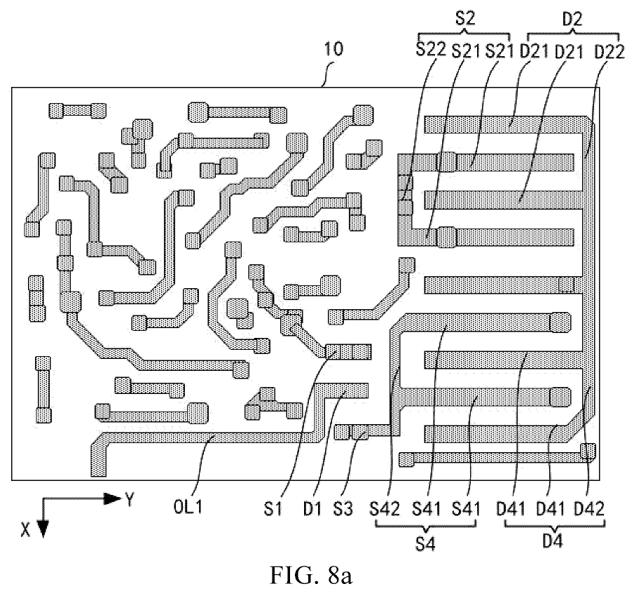

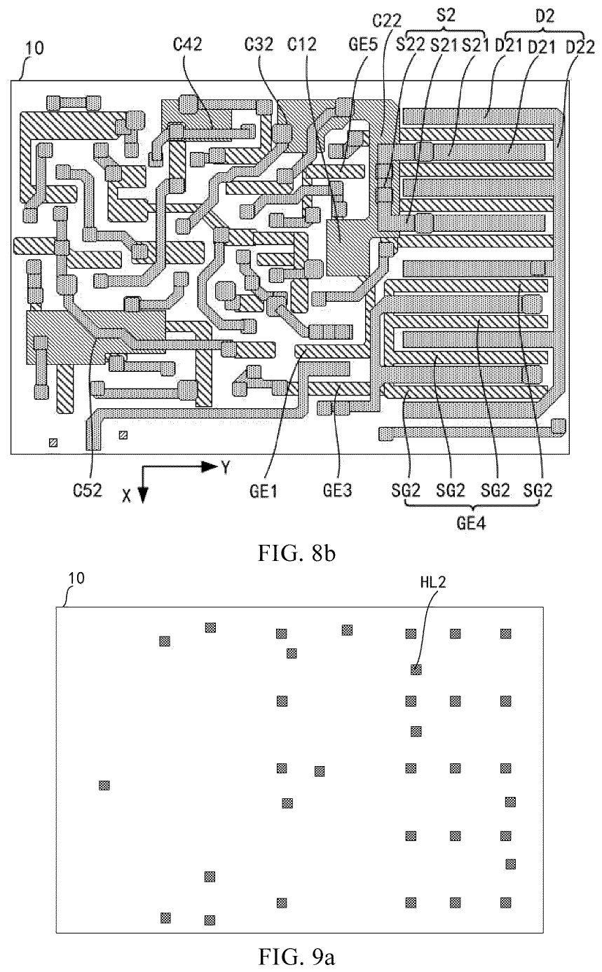

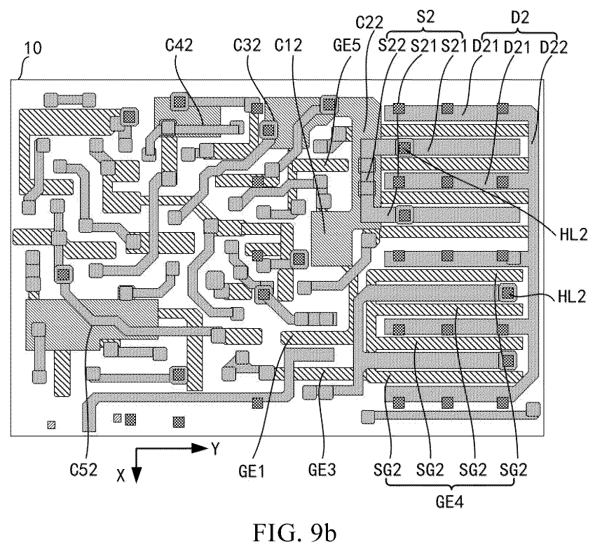

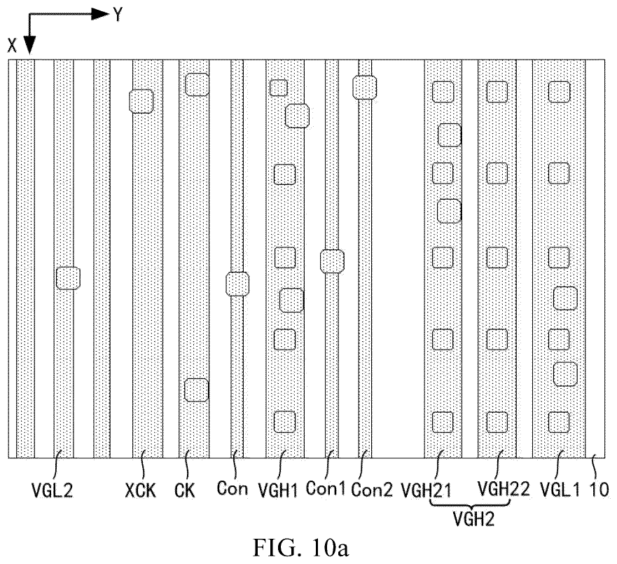

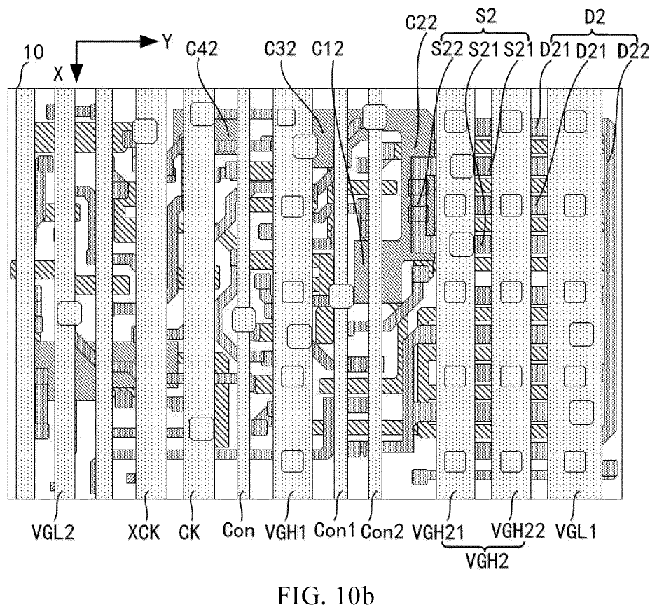

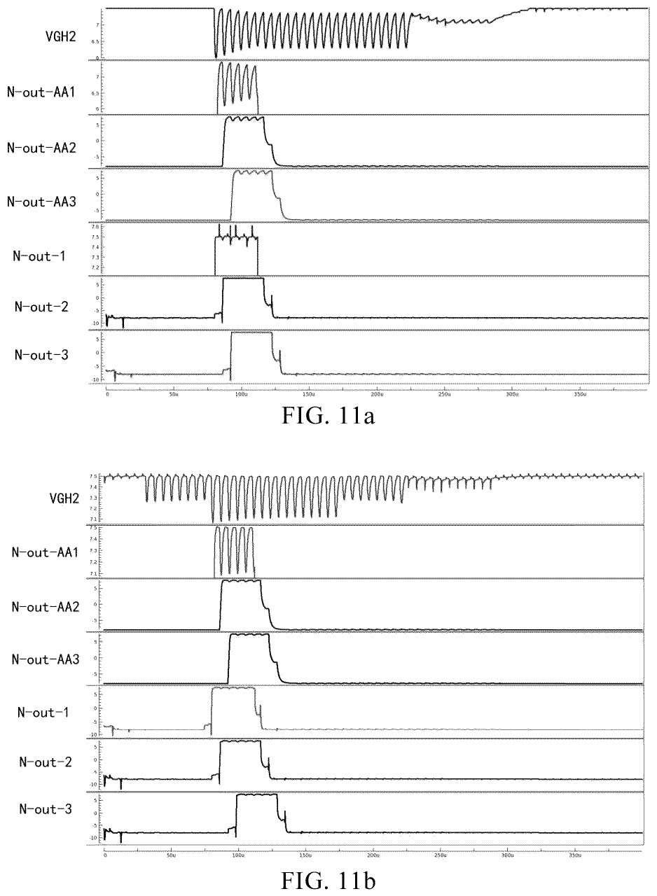

The following specifically elaborates on the structure of the first capacitor C3, the second capacitor C4, the third capacitor C5, and the second output transistor T22:
Referencing FIGS. 1 to 10b, FIGS. 4a to 10b show schematic views of some of the layer stack-ups from FIG. 3, and FIGS. 11a and 11b are schematic diagrams of simulation data provided in the present application. Specifically, FIG. 4a is a schematic plan view of an active layer of each transistor in FIG. 3, FIG. 4b is a plan schematic plan view of a first metal layer in FIG. 3, and FIG. 4c is a schematic view of a stack-up of the active layer from FIG. 4a with the first metal layer from FIG. 4b. FIG. 5a is a schematic plan view of a light-shielding layer in FIG. 3. FIG. 5b is a schematic view of a stack-up of the light-shielding layer from FIG. 3 with FIG. 4c. FIG. 6a is a schematic plan view of a second metal layer in FIG. 3, and FIG. 6b is a schematic view of a stack-up of the second metal layer from FIG. 6a with the first metal layer from FIG. 4b. FIG. 7a is a schematic plan view showing vias in an interlayer dielectric layer in FIG. 3, and FIG. 7b is a schematic view of a stack-up of FIG. 7a with FIG. 6b. FIG. 8a is a schematic plan view of a third metal layer in FIG. 3, and FIG. 8b is a schematic view of a stack-up of FIG. 8a with FIG. 6b. FIG. 9a is a schematic plan view of vias in a planarization layer in FIG. 3, and FIG. 9b is a schematic view of a stack-up of FIG. 9a with FIG. 8b. FIG. 10a is a schematic plan view of a fourth metal layer in FIG. 3, and FIG. 10b is a schematic view of a stack-up of FIG. 10a with FIG. 9b.

Specifically, the display panel 100 further includes a substrate 10 and, stacked in sequence on the substrate 10, a light-shielding layer, an active layer, a first metal layer, a second metal layer, an interlayer insulation layer, a third metal layer, a planarization layer, and a fourth metal layer.

Referring to FIGS. 4a to 4c, the active layer is disposed on the substrate 10, and the first metal layer is positioned on one side of the active layer that is away from the substrate 10. The first metal layer includes a gate GE1 of the first output transistor T10, a gate GE2 of the second output transistor T22, a gate GE3 of the third output transistor T9, a gate GE4 of the fourth output transistor T21, a gate GE5 of the first frequency dividing transistor T18, a first plate C11 of the first capacitor C3, a first plate C21 of the second capacitor C4, a first plate C31 of the third capacitor C5, a first plate C41 of the fourth capacitor C2, and a first plate C51 of the fifth capacitor C1. Certainly, the first metal layer also includes the gates of other transistors, such as the gates of the first transistor T4, the second transistor T5, and other transistors.

The gate GE1 of the first output transistor T10 is positioned above an active layer AS1 of the first output transistor T10, the gate GE2 of the second output transistor T22 is positioned above an active layer AS2 of the second output transistor T22, the gate GE3 of the third output transistor T9 is positioned above an active layer AS3 of the third output transistor T9, the gate GE4 of the fourth output transistor T21 is positioned above an active layer AS4 of the fourth output transistor T21, and the gate GE5 of the first frequency dividing transistor T18 is positioned above an active layer AS5 of the first frequency dividing transistor T18.

The gate GE2 of the second output transistor T22 includes multiple first sub-traces SG1 extending along the second direction Y. There is a first gap between each adjacent pair of the first sub-traces SG1, and each of the first sub-traces SG1 is connected to the first plate C21 of the second capacitor C4. The first plate C21 of the second capacitor C4 is located on the same side of the multiple first sub-traces SG1 and extends along the first direction X.

The gate GE4 of the fourth output transistor T21 includes multiple tenth sub-traces SG2 extending along the second direction Y. There is a second gap between each adjacent pair of the tenth sub-traces SG2, and each of the tenth sub-traces SG2 is connected to the gate GE3 of the third output transistor T9.

Referring to FIGS. 5a and 5b, the light-shielding layer is positioned on one side of the substrate 10, the active layer is positioned on one side of the light-shielding layer away from the substrate 10, and the first metal layer is positioned on one side of the active layer away from the light-shielding layer. The light-shielding layer serves to shield light for certain transistors and overlaps second gates of these transistors; for example, the light-shielding layer can shield light for the third output transistor T9, the second shielding transistor T12, the third shielding transistor T15, and the eighth transistor T16, and act as a second gate GE9 of the third output transistor T9, a second gate GE12 of the second shielding transistor T12, a second gate GE15 of the third shielding transistor T15, and a second gate GE16 of the eighth transistor T16.

Referring to FIGS. 6a and 6b, the second metal layer is positioned on one side of the first metal layer away from the substrate 10. Certainly, a gate insulating layer is also placed between the first metal layer and the second metal layer to electrically isolate the first metal layer from the second metal layer. The second metal layer includes a second plate C12 of the first capacitor C3, a second plate C22 of the second capacitor C4, a second plate C32 of the third capacitor C5, a second plate C42 of the fourth capacitor C2, and a second plate C52 of the fifth capacitor C1. The second plate C12 of the first capacitor C3, the second plate C22 of the second capacitor C4, and the second plate C32 of the third capacitor C5 are integrally formed, such as the second plate C22 of the second capacitor C4 being connected between the second plate C12 of the first capacitor C3 and the second plate C32 of the third capacitor C5.

Referring to FIGS. 7a and 7b, the interlayer insulation layer is positioned on one side of the second metal layer away from the first metal layer. A plurality of first vias HL1 are created in the interlayer insulation layer, for example, the interlayer insulation layer is provided with the first vias HL1 positioned corresponding to the second plate C22 of the second capacitor C4. The first via HL1 exposes part of the second plate C22 of the second capacitor C4.

Referring to FIGS. 8a and 8b, the third metal layer is positioned on one side of the second metal layer away from the first metal layer, with the interlayer insulation layer located between the third metal layer and the second metal layer. The third metal layer includes a source S1 and a drain D1 of the first output transistor T10, a source S2 and a drain D2 of the second output transistor T22, a source S3 and a drain D1 of the third output transistor T9, a source S4 and a drain D4 of the fourth output transistor T21, and a first output line OL1. The drain D1 of the first output transistor T10 and the drain D1 of the third output transistor T9 are connected to the first output line OL1. The source S3 of the third output transistor T9 is connected to the source S4 of the fourth output transistor T21.

The source S2 of the second output transistor T22 includes multiple second sub-traces S21 extending along the second direction Y and a third sub-trace S22 that connects the multiple second sub-traces S21. The third sub-trace S22 extends along the first direction X and is positioned corresponding to the second plate C22 of the second capacitor C4. The third sub-trace S22 connects through the first via HL1 in the interlayer insulation layer to the second plate C22 of the second capacitor C4.

The drain D2 of the second output transistor T22 includes multiple fourth sub-traces D21 extending along the second direction Y and a fifth sub-trace D22 that connects the multiple fourth sub-traces D21. The fifth sub-trace D22 extends along the first direction X and is positioned on one side of the fourth sub-traces D21 away from the third sub-trace S22. The fifth sub-trace D22 connects to the second output line. Both the second sub-traces S21 and the fourth sub-traces D21 are arranged corresponding to the first gaps and are located on two opposite sides of the first sub-trace SG1.

The source S4 of the fourth output transistor T21 includes multiple sixth sub-traces S41 extending along the second direction Y and a seventh sub-trace S42 that connects the multiple sixth sub-traces S41. The seventh sub-trace S42 extends along the first direction X. The drain D4 of the fourth output transistor T21 includes multiple eighth sub-traces D41 extending along the second direction Y and a ninth sub-trace D42 that connects the multiple eighth sub-traces D41. The ninth sub-trace D42 extends along the first direction X and is located on one side of the eighth sub-traces D41 away from the seventh sub-trace S42, and the ninth sub-trace D42 connects to the second output line. Both the sixth sub-traces S41 and the eighth sub-traces D41 are arranged corresponding to the second gaps and are located on two opposite sides of the tenth sub-trace SG2.

Referring to FIGS. 9a and 9b, the planarization layer is positioned on one side of the third metal layer away from the interlayer insulation layer. The planarization layer is provided with multiple second vias HL2, for example, the planarization layer has the second vias HL2 positioned corresponding to the locations of the second sub-traces S21. The second vias HL2 expose parts of the second sub-traces S21. The second vias are located on one side of the second sub-traces S21 close to the third sub-trace S22. The planarization layer is also provided with the second vias HL2 positioned corresponding to the sixth sub-traces S41. The second sub-traces S21 expose parts of the sixth sub-traces S41.

Referring to FIGS. 10a and 10b, the fourth metal layer is positioned on one side of the third metal layer that is away from the second metal layer, with the planarization layer located between the fourth metal layer and the third metal layer. The fourth metal layer includes the first power line VGH1, the second power line VGH2, the third power line VGL1, the fourth power line VGL2, the first clock signal line XCK, the second clock signal line CK, the power-on reset control line Con, the first frequency division control signal line Con2, and the second frequency division control signal line Con1, which all extend along the first direction X. The second power line VGH2 is connected to the second sub-trace S21 through the second via HL2 in the planarization layer, and the third power line VGL1 is connected to the sixth sub-trace S41 through the second via HL2 in the planarization layer.

The second power line VGH2 includes a first sub-power line VGH21 and a second sub-power line VGH22 spaced apart from each other. Some of the gate driving circuits GDC have the second output transistor T22 connected to the first sub-power line VGH21, while another set within the gate driving circuits GDC have the second output transistor T22 connected to the second sub-power line VGH22.

In any two adjacent stages of the gate driving circuits GDC, the second output transistor T22 in one stage of the gate driving circuit GDC is connected to the first sub-power line VGH21, and in the other stage of the gate driving circuit GDC, the second output transistor T22 is connected to the second sub-power line VGH22.

Referring to FIGS. 11a and 11b, FIG. 11a shows a schematic diagram of the waveform of the output signals at various stages of the gate driving circuits in conventional technology, while FIG. 11b shows a schematic diagram of the waveform of the output signals at various stages of the gate driving circuits according to the present application. When a load on the second power line VGH2 is small, there is a fluctuation of about 1V, causing similar fluctuations in the high pulse signal of the gate control signal N_out_AA from the gate driving circuit, as shown in FIG. 11a. When the load on the second power line VGH2 is larger, the fluctuation decreases to 0.4V, and the fluctuation of the high pulse signal corresponding to the gate control signal N_out_AA also reduces to 0.4V. This means that when the overall output on the second power line VGH2 is small, the output of each row's gate control signal N_out_AA from the gate driving circuit is more significantly disturbed. However, by increasing the overall capacitance on the second power line VGH2, the stability of the gate control signal N_out_AA from the gate driving circuit is improved.

Based on the same inventive concept, the present application further provides a display device that includes one of the display panels as described in the above embodiments. The display device can include, but is not limited to, wearable devices such as smart bands, smart watches, Virtual Reality (VR), mobile phones, televisions, and personal portable computers.

From the above embodiments, it can be known:

The display panel and the display device provided in this application improve the stability of the gate driving circuit's output signals by connecting the first and second capacitors to the second power line which is connected to the second output transistor. This increases the overall capacitance on the second power line, reduces the voltage drop on the second power line, and thereby addresses the technical issue of fluctuations in the high-level output of conventional GOA circuits affecting the stability of the output signals.

In the above embodiments, each description of the various embodiments focuses on different aspects. For details not elaborated in a particular embodiment, reference can be made to the descriptions related to other embodiments.

The embodiments of the present application have been described in detail above, with specific examples used to explain the principles and embodiments of this application. The descriptions of the above embodiments are intended only to help understand the technology and core ideas of this application; those of ordinary skill in the art should understand that they can still make modifications to the previously recorded technical solutions of each embodiment, or equivalently substitute some of their technical features; and these modifications or substitutions do not cause the essence of the corresponding technical solutions to deviate from the scope of the technical solutions of the embodiments of this application.

What is claimed is:

1. A display panel, comprising:
a first power line and a second power line arranged along a first direction and spaced apart along a second direction, wherein the first direction and the second direction are different; and
multiple stages of gate driving circuits in a cascaded arrangement, wherein the gate driving circuits are configured to generate multiple gate control signals for output to a plurality of sub-pixels of the display panel, and each of the gate driving circuits comprises:
a start transistor, wherein a gate of the start transistor is configured to receive a corresponding clock signal, and a source of the start transistor is configured to receive a start signal;
a first output transistor, wherein a gate of the first output transistor is electrically connected to a drain of the start transistor, a source of the first output transistor is connected to the first power line, and a drain of the first output transistor is connected to a first output line of the gate driving circuit of the current stage;
a first capacitor, wherein a first plate of the first capacitor is connected to the gate of the first output transistor;
a second output transistor, wherein a gate of the second output transistor is electrically connected to the gate of the first output transistor, a source of the second output transistor is connected to the second power line, and a drain of the second output transistor is connected to a second output line of the gate driving circuit of the current stage; and
a second capacitor, wherein a first plate of the second capacitor is connected to the gate of the second output transistor and electrically connected to the first plate of the first capacitor, wherein a second plate of the second capacitor is connected to a second plate of the first capacitor, also connected to the source of the second output transistor, and is connected through the source of the second output transistor to the second power line.

2. The display panel according to claim 1, wherein each of the gate driving circuits further comprises a third capacitor, and a second plate of the third capacitor is connected to the second plate of the second capacitor.

3. The display panel according to claim 2, wherein each of the gate driving circuits further comprises a first frequency dividing transistor, a gate of the first frequency dividing transistor is connected to a first plate of the third capacitor, a source of the first frequency dividing transistor is connected to the first plate of the first capacitor, and a drain of the first frequency dividing transistor is connected to the first plate of the second capacitor.

4. The display panel according to claim 2, wherein the first plate of the first capacitor, the first plate of the second capacitor, and a first plate of the third capacitor are integrally formed as a single unit and located between the first power line and the second power line.

5. The display panel according to claim 2, wherein the gate of the second output transistor comprises a plurality of first sub-traces extending along the second direction, a first gap is established between each adjacent pair of the first sub-traces, each of the first sub-traces is connected to the first plate of the second capacitor, and the first plate of the second capacitor is located on a same side of the first sub-traces and extends along the first direction;
the source of the second output transistor comprises a plurality of second sub-traces extending along the second direction and a third sub-trace that connects the second sub-traces, the third sub-trace extends along the first direction, the third sub-trace is disposed corresponding to the second plate of the second capacitor and is connected to the second plate of the second capacitor, and the second sub-traces are connected to the second power line;
the drain of the second output transistor comprises a plurality of fourth sub-traces extending along the second direction and a fifth sub-trace that connects the fourth sub-traces, the fifth sub-trace extends along the first direction and is disposed on one side of the fourth sub-traces away from the third sub-trace, and the fifth sub-trace is connected to the second output line;
wherein both the second sub-traces and the fourth sub-traces are arranged corresponding to the first gaps and are located on two opposite sides of the first sub-traces.

6. The display panel according to claim 5, wherein the second power line comprises a first sub-power line and a second sub-power line, the second output transistors within some of the gate driving circuits are connected to the first sub-power line, while the second output transistors within the remaining gate driving circuits are connected to the second sub-power line.

7. The display panel according to claim 6, wherein among any two adjacent stages of the gate driving circuits, the second output transistor within one stage of the gate driving circuits is connected to the first sub-power line, while the second output transistor within the other stage of the gate driving circuits is connected to the second sub-power line.

8. The display panel according to claim 5, further comprising:
a substrate;
a first metal layer disposed on the substrate, wherein the first metal layer comprises the gate of the first output transistor, the gate of the second output transistor, the first plate of the first capacitor, the first plate of the second capacitor, a first plate of the third capacitor, and the second output line;
a second metal layer disposed on one side of the first metal layer away from the substrate, wherein the second metal layer comprises the second plate of the first capacitor, the second plate of the second capacitor, and the second plate of the third capacitor;
a third metal layer disposed on one side of the second metal layer away from the first metal layer, wherein the third metal layer comprises the source of the first output transistor, the drain of the first output transistor, the source of the second output transistor, the drain of the second output transistor, and the first output line; and
a fourth metal layer disposed on one side of the third metal layer away from the second metal layer, wherein the fourth metal layer comprises the first power line and the second power line.

9. The display panel according to claim 1, further comprising a third power line extending along the first direction, with the third power line located on one side of the second power line away from the first power line,
wherein each of the gate driving circuits further comprises a third output transistor and a fourth output transistor, a gate of the third output transistor is connected to a gate of the fourth output transistor, a source of the third output transistor is connected to a source of the fourth output transistor, a drain of the third output transistor is connected to the first output line, the source of the fourth output transistor is connected to the third power line, and a drain of the fourth output transistor is connected to the second output line.

10. The display panel according to claim 9, wherein along the second direction, a width of the third power line is greater than a width of both the second power line and the first power line.

11. A display device, comprising a display panel, wherein the display panel comprises:
a first power line and a second power line arranged along a first direction and spaced apart along a second direction, wherein the first direction and the second direction are different; and
multiple stages of gate driving circuits in a cascaded arrangement, wherein the gate driving circuits are configured to generate multiple gate control signals for output to a plurality of sub-pixels of the display panel, and each of the gate driving circuits comprises:
a start transistor, wherein a gate of the start transistor is configured to receive a corresponding clock signal, and a source of the start transistor is configured to receive a start signal;
a first output transistor, wherein a gate of the first output transistor is electrically connected to a drain of the start transistor, a source of the first output transistor is connected to the first power line, and a drain of the first output transistor is connected to a first output line of the gate driving circuit of the current stage;
a first capacitor, wherein a first plate of the first capacitor is connected to the gate of the first output transistor;
a second output transistor, wherein a gate of the second output transistor is electrically connected to the gate of the first output transistor, a source of the second output transistor is connected to the second power line, and a drain of the second output transistor is connected to a second output line of the gate driving circuit of the current stage; and
a second capacitor, wherein a first plate of the second capacitor is connected to the gate of the second output transistor and electrically connected to the first plate of the first capacitor, wherein a second plate of the second capacitor is connected to a second plate of the first capacitor, also connected to the source of the second output transistor, and is connected through the source of the second output transistor to the second power line.

12. The display device according to claim 11, wherein each of the gate driving circuits further comprises a third capacitor, and a second plate of the third capacitor is connected to the second plate of the second capacitor.

13. The display device according to claim 12, wherein each of the gate driving circuits further comprises a first frequency dividing transistor, a gate of the first frequency dividing transistor is connected to a first plate of the third capacitor, a source of the first frequency dividing transistor is connected to the first plate of the first capacitor, and a drain of the first frequency dividing transistor is connected to the first plate of the second capacitor.

14. The display device according to claim 12, wherein the first plate of the first capacitor, the first plate of the second capacitor, and a first plate of the third capacitor are integrally formed as a single unit and located between the first power line and the second power line.

15. The display device according to claim 12, wherein the gate of the second output transistor comprises a plurality of first sub-traces extending along the second direction, a first gap is established between each adjacent pair of the first sub-traces, each of the first sub-traces is connected to the first plate of the second capacitor, and the first plate of the second capacitor is located on a same side of the first sub-traces and extends along the first direction;
the source of the second output transistor comprises a plurality of second sub-traces extending along the second direction and a third sub-trace that connects the second sub-traces, the third sub-trace extends along the first direction, the third sub-trace is disposed corresponding to the second plate of the second capacitor and is connected to the second plate of the second capacitor, and the second sub-traces are connected to the second power line;
the drain of the second output transistor comprises a plurality of fourth sub-traces extending along the second direction and a fifth sub-trace that connects the fourth sub-traces, the fifth sub-trace extends along the first direction and is disposed on one side of the fourth sub-traces away from the third sub-trace, and the fifth sub-trace is connected to the second output line;
wherein both the second sub-traces and the fourth sub-traces are arranged corresponding to the first gaps and are located on two opposite sides of the first sub-traces.

16. The display device according to claim 15, wherein the second power line comprises a first sub-power line and a second sub-power line, the second output transistors within some of the gate driving circuits are connected to the first sub-power line, while the second output transistors within the remaining gate driving circuits are connected to the second sub-power line.

17. The display device according to claim 16, wherein among any two adjacent stages of the gate driving circuits, the second output transistor within one stage of the gate driving circuits is connected to the first sub-power line, while the second output transistor within the other stage of the gate driving circuits is connected to the second sub-power line.

18. The display device according to claim 15, further comprising:
a substrate;
a first metal layer disposed on the substrate, wherein the first metal layer comprises the gate of the first output transistor, the gate of the second output transistor, the first plate of the first capacitor, the first plate of the second capacitor, a first plate of the third capacitor, and the second output line;
a second metal layer disposed on one side of the first metal layer away from the substrate, wherein the second metal layer comprises the second plate of the first capacitor, the second plate of the second capacitor, and the second plate of the third capacitor;
a third metal layer disposed on one side of the second metal layer away from the first metal layer, wherein the third metal layer comprises the source of the first output transistor, the drain of the first output transistor, the source of the second output transistor, the drain of the second output transistor, and the first output line; and
a fourth metal layer disposed on one side of the third metal layer away from the second metal layer, wherein the fourth metal layer comprises the first power line and the second power line.

19. The display device according to claim 11, further comprising a third power line extending along the first direction, with the third power line located on one side of the second power line away from the first power line,
wherein each of the gate driving circuits further comprises a third output transistor and a fourth output transistor, a gate of the third output transistor is connected to a gate of the fourth output transistor, a source of the third output transistor is connected to a source of the fourth output transistor, a drain of the third output transistor is connected to the first output line, the source of the fourth output transistor is connected to the third power line, and a drain of the fourth output transistor is connected to the second output line.

20. The display device according to claim 19, wherein along the second direction, a width of the third power line is greater than a width of both the second power line and the first power line.
